(19) United States
(12) Patent Application Publication
(10) Pub. No.: US 2025/0151286 A1
(43) Pub. Date: May 8, 2025

(54) SEMICONDUCTOR DEVICE

(71) Applicant: Samsung Electronics Co., Ltd., Suwon-si (KR)

(72) Inventors: Jonghyun PAEK, Suwon-si (KR); Seulji SONG, Suwon-si (KR)

(73) Assignee: Samsung Electronics Co., Ltd., Suwon-si (KR)

(21) Appl. No.: 18/680,492

(22) Filed: May 31, 2024

(30) Foreign Application Priority Data
Nov. 6, 2023 (KR) 10-2023-0152145

(51) Int. Cl. H10B 63/00; H01L 29/06; H01L 29/417; H01L 29/423; H01L 29/775; H01L 29/786; H10N 70/00

(52) U.S. Cl. CPC H10B 63/34; H10B 63/845; H10D 30/43; H10D 30/6729; H10D 30/6735; H10D 30/6757; H10D 62/121; H10N 70/841

(57) ABSTRACT

A semiconductor device includes a plurality of word lines extending in a first direction; a plurality of bit lines extending in a second direction crossing the first direction; a plurality of memory cells in a plurality of areas in which the plurality of word lines and the plurality of bit lines intersect; and a semiconductor element connected to at least one of the plurality of word lines and the plurality of bit lines, the semiconductor element including a first active pattern and a second active pattern overlapping the first active pattern along a height direction perpendicular to the first and second directions.

### CROSS-REFERENCE TO RELATED APPLICATION

This application claims priority to and the benefit of Korean Patent Application No. 10-2023-0152145 filed in the Korean Intellectual Property Office on Nov. 6, 2023, the entire contents of which are incorporated herein by reference.

### BACKGROUND

The present disclosure relates to semiconductor devices.

A semiconductor is a material belonging to a class of materials that is intermediate a conductor and an insulator, and is a material that conducts electricity under predetermined conditions. Various semiconductor elements can be manufactured by using semiconductor material, and for example, a memory device and the like may be manufactured. Semiconductor elements may be used in various electronic devices.

In the semiconductor industry, demand for high capacity, thinned, and down-sized semiconductor elements and electronic products using the same is increasing.

According to the trend of providing down-sized and highly integrated electronic elements, there is a need to accurately and quickly apply signals to semiconductor devices while reducing an area occupied by peripheral portions for applying desired (and/or alternatively predetermined) signals to the semiconductor elements.

### SUMMARY

Some example embodiments of the inventive concepts provide a semiconductor device that may simplify a structure of a memory cell and may reduce an area occupied by a peripheral portion that applies a desired (and/or alternatively predetermined) signal to the memory cell.

However, problems to be solved by example embodiments are not limited to the above-described problems and may be variously extended in a range of technical ideas included in some example embodiments.

Some example embodiments of the inventive concepts provide a semiconductor device that includes a plurality of word lines extending in a first direction; a plurality of bit lines extending in a second direction crossing the first direction; a plurality of memory cells in a plurality of areas in which the plurality of word lines and the plurality of bit lines intersect; and a semiconductor element connected to at least one of the plurality of word lines and the plurality of bit lines. The semiconductor element includes a first active pattern and a second active pattern overlapping the first active pattern along a height direction perpendicular to the first and second directions.

According to some example embodiments, it may thus be possible to provide a semiconductor device that may simplify a structure of a memory cell and may reduce an area occupied by a peripheral portion that applies a desired (and/or alternatively predetermined) signal to the memory cell.

It is to be understood that the effect of some example embodiments is not limited to the above-described effect, and may be variously extended without departing from the spirit and scope of the inventive concepts.

### BRIEF DESCRIPTION OF THE DRAWINGS

FIG. 1 illustrates a perspective view of a semiconductor device including a memory cell according to some example embodiments of the inventive concepts.

FIG. 2 illustrates a memory cell in a first memory layer and a corresponding word line and bit line connected thereto according to some example embodiments of the inventive concepts.

FIG. 3 illustrates a memory cell in a second memory layer and a corresponding word line and bit line connected thereto according to some example embodiments of the inventive concepts.

FIG. 4 illustrates a memory cell in a third memory layer and a corresponding word line and bit line connected thereto according to some example embodiments of the inventive concepts.

FIG. 5 illustrates a memory cell in a fourth memory layer and a corresponding word line and bit line connected thereto according to some example embodiments of the inventive concepts.

FIG. 6 illustrates a simplified cross-sectional view of semiconductor elements of a peripheral circuit connected to a memory layer of a semiconductor device according to some example embodiments of the inventive concepts.

FIG. 7 illustrates an enlarged view of the semiconductor element of the peripheral circuit of FIG. 6.

FIG. 8 illustrates a circuit diagram of the semiconductor element of the peripheral circuit of FIG. 7.

FIG. 9 illustrates a perspective view of a semiconductor element in a peripheral area of a semiconductor device according to some example embodiments of the inventive concepts.

FIG. 10 illustrates a cross-sectional view taken along line A-A of FIG. 9.

FIG. 11 illustrates a cross-sectional view taken along line B-B of FIG. 9.

FIG. 12 illustrates a cross-sectional view taken along line C-C of FIG. 9.

FIG. 13 illustrates a block diagram of a semiconductor device according to some example embodiments of the of the inventive concepts.

### DETAILED DESCRIPTION

The of the inventive concepts will be described more fully hereinafter with reference to the accompanying drawings, in which some example embodiments are shown. As those skilled in the art would realize, the described example embodiments may be modified in various different ways, all without departing from the spirit or scope of the inventive concepts.

In order to clearly describe the inventive concepts, parts or portions that are irrelevant to the description are omitted, and identical or similar constituent elements throughout the specification are denoted by the same reference numerals.

The accompanying drawings are provided only in order to allow some example embodiments disclosed in the present specification to be easily understood and are not to be interpreted as limiting the scope of the inventive concepts, and it is to be understood that the inventive concepts include all modifications, equivalents, and substitutions without departing from the scope and spirit of the thereof.

Further, in the drawings, the size and thickness of each element are arbitrarily illustrated for ease of description, and the inventive concepts are not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, various some example embodiments and variations will be described in detail with reference to the drawings.

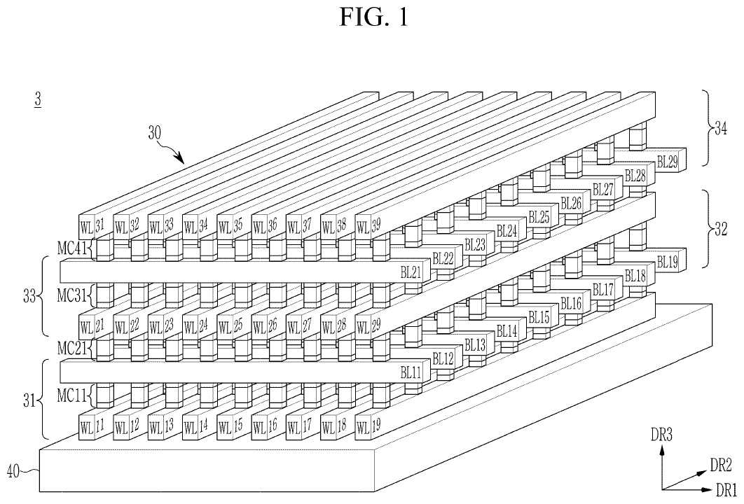

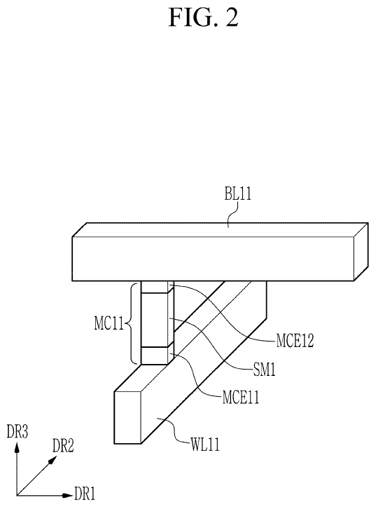

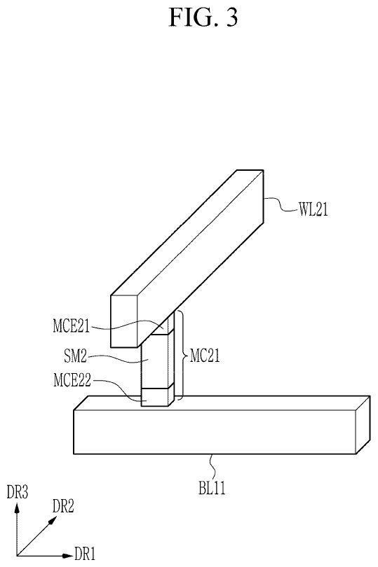

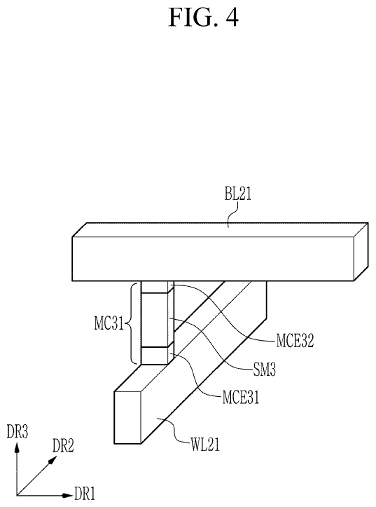

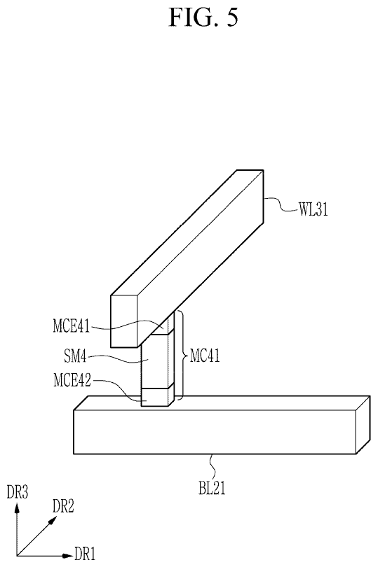

A semiconductor device including a memory cell according to an some example embodiments will be described with reference to FIG. 1 to FIG. 5. FIG. 1 illustrates a three-dimensional perspective view of a semiconductor device including a memory cell according to some example embodiments, FIG. 2 illustrates a memory cell in a first memory layer of FIG. 1 and a corresponding word line and bit line connected thereto, FIG. 3 illustrates a memory cell in a second memory layer of FIG. 1 and a corresponding word line and bit line connected thereto, FIG. 4 illustrates a memory cell in a third memory layer of FIG. 1 and a corresponding word line and bit line connected thereto, and FIG. 5 illustrates a memory cell in a fourth memory layer of FIG. 1 and a corresponding word line and bit line connected thereto.

Referring to FIG. 1, a memory device 3 according to some example embodiments may include a memory cell array 30 and a peripheral circuit 40.

The memory device 3 according to some example embodiments shown in FIG. 1 may be a memory device on a wafer or a semiconductor device separated from the wafer to be combined with other components.

The memory cell array 30 may have a multi-deck structure. The memory cell array 30 according to some example embodiments may include a plurality of memory layers. Referring to FIG. 1, the memory cell array 30 according to some example embodiments may include a first memory layer 31, a second memory layer 32, a third memory layer 33, and a fourth memory layer 34, but the example embodiments are not limited thereto, and the number of memory layers included in the memory cell array 30 may be changed. The structure of the memory cell array 30 illustrated in FIG. 1 is an example for explaining the inventive concepts, and the inventive concepts are not limited thereto.

The memory cell array 30 may include a plurality of memory cells respectively disposed in areas in which a plurality of first signal lines and a plurality of second signal lines intersect. In some example embodiments, the first signal line may be one of a bit line and a word line, and the second signal line may be the other of the bit line and the word line. Each of the plurality of memory cells may be a single level cell storing one bit or a multi-level cell storing at least two bits of data or more. The memory cells may have a plurality of resistance distributions according to the number of bits stored in each memory cell. For example, when 1 bit of data is stored in each memory cell, the memory cells may have two resistance distributions, and when 2 bits of data are stored in each memory cell, the memory cells may have four resistance distributions.

Each of the plurality of memory cells may be a resistive memory cell including a variable resistance element. For example, the variable resistance element may include a phase change material, and when resistance changes according to temperature, a resistive memory device may be a phase-change memory (PRAM). For example, the variable resistance element may include an upper electrode, a lower electrode, and a complex metal oxide interposed therebetween, and a resistive memory device may be a resistive RAM (RRAM). For example, the variable resistance element may include a magnetic upper electrode, a magnetic lower electrode, and a dielectric therebetween, and a resistive memory device may be a magnetic RAM (MRAM). The memory cell of some example embodiments in the present disclosure may be a resistive memory cell.

The peripheral circuit 40 may be disposed below the memory cell array 30 and may be electrically connected to the memory cell array 30. For example, the plurality of memory layers 31, 32, 33, and 34 may be sequentially disposed on the peripheral circuit 40. The peripheral circuit 40 may include a plurality of wires connected to a plurality of bit lines BL11 to BL19 and BL21 to BL29 and a plurality of wires connected to a plurality of word lines WL11 to WL19, WL21 to WL29, and WL31 to WL39. A voltage may be applied to each of the plurality of bit lines BL11 to BL19 and BL21 to BL29 and the plurality of word lines WL11 to WL19, WL21 to WL29, and WL31 to WL39 through the plurality of wires in peripheral circuit 40.

The memory cell array 30 includes the plurality of memory layers 31, 32, 33, and 34, and two adjacent memory layers of the plurality of memory layers 31, 32, 33, and 34 may share the plurality of bit lines BL11 to BL19 and BL21 to BL29 and the plurality of word lines WL11 to WL19, WL21 to WL29, and WL31 to WL39.

The plurality of bit lines BL11 to BL19 and BL21 to BL29 may include a plurality of first bit lines BL11 to BL19 and a plurality of second bit lines BL21 to BL29 extending in a first direction DR1.

The plurality of first bit lines BL11 to BL19 may be shared by the first memory layer 31 and the second memory layer 32.

The plurality of second bit lines BL21 to BL29 may be shared by the third memory layer 33 and the fourth memory layer 34.

The plurality of word lines WL11 to WL19, WL21 to WL29, and WL31 to WL39 may extend in a second direction DR2. The plurality of word lines WL11 to WL19, WL21 to WL29, and WL31 to WL39 may include a plurality of first word lines WL11 to WL19, a plurality of second word lines WL21 to WL29, and a plurality of third words lines WL31 to WL39.

The plurality of first word lines WL11 to WL19 are disposed on an upper portion of the peripheral circuit 40, and may be connected to the first memory layer 31.

The plurality of second word lines WL21 to WL29 may be shared by the second memory layer 32 and the third memory layer 33. The plurality of third word lines WL31 to WL39 may be disposed at an upper portion of the fourth memory layer 34.

The plurality of memory cells may be disposed in a plurality of areas in which the plurality of bit lines BL11 to BL19 and BL21 to BL29 and the plurality of word lines WL11 to WL19, WL21 to WL29, and WL31 to WL39 intersect.

Referring to FIG. 2, one memory cell MC11 of the first memory layer 31 may include a first electrode MCE11, a switch memory SM1 stacked on the first electrode MCE11, and a second electrode MCE12 stacked on the switch memory SM1. In FIG. 2, for better understanding and ease of description, one word line WL11, one bit line BL11, and the memory cell MC11 disposed in an intersection area of two signal lines WL11 and BL11 are illustrated.

The first electrode MCE11 may contact the corresponding word line WL11, the second electrode MCE12 may contact the corresponding bit line BL11, and the switch memory SM1 may be disposed between the first electrode MCE11 and the second electrode MCE12. The switch memory SM1 may have a structure in which a switching element and a memory element are combined, and may be an ovonic threshold switch (OTS). For example, the ovonic threshold switch may include chalcogenide. When the voltage applied to both ends of the switch memory SM1 is lower than a desired (and/or alternatively predetermined) threshold, no current flows in the switch memory SM1, and when the voltage is higher than a desired (and/or alternatively predetermined) reference voltage, the current in the switch memory SM1 may rapidly increase. According to some example embodiments, the switch memory SM1 may be an oxide-based switching selection device using the metal-insulator transition phenomenon of oxide. However, some example embodiments are not limited thereto.

Referring to FIG. 3, one memory cell MC21 of the second memory layer 32 may include a second electrode MCE22, a switch memory SM2 stacked on the second electrode MCE22, and a first electrode MCE21 stacked on the switch memory SM2. In FIG. 3, for better understanding and ease of description, the word line WL21, the bit line BL11, and the memory cell MC21 disposed in the intersection area are illustrated.

The first electrode MCE21 may contact the corresponding word line WL21, the second electrode MCE22 may contact the corresponding bit line BL11, and the switch memory SM2 may be disposed between the first electrode MCE21 and the second electrode MCE22.

Referring to FIG. 4, one memory cell MC31 of the third memory layer 33 may include a first electrode MCE31, a switch memory SM3 stacked on the first electrode MCE31, and a second electrode MCE32 stacked on the switch memory SM3. In FIG. 4, for better understanding and ease of description, the word line WL21, the bit line BL21, and the memory cell MC31 disposed in the intersection area are illustrated.

The first electrode MCE31 may contact the corresponding word line WL21, the second electrode MCE32 may contact the corresponding bit line BL21, and the switch memory SM3 may be disposed between the first electrode MCE31 and the second electrode MCE32.

Referring to FIG. 5, one memory cell MC41 of the fourth memory layer 34 may include a second electrode MCE42, a switch memory SM4 stacked on the second electrode MCE42, and a first electrode MCE41 stacked on the switch memory SM4. In FIG. 5, for better understanding and ease of description, the word line WL31, the bit line BL21, and the memory cell MC41 disposed in the intersection area are illustrated.

The first electrode MCE41 may contact the corresponding word line WL31, the second electrode MCE42 may contact the corresponding bit line BL21, and the switch memory SM4 may be disposed between the first electrode MCE41 and the second electrode MCE42.

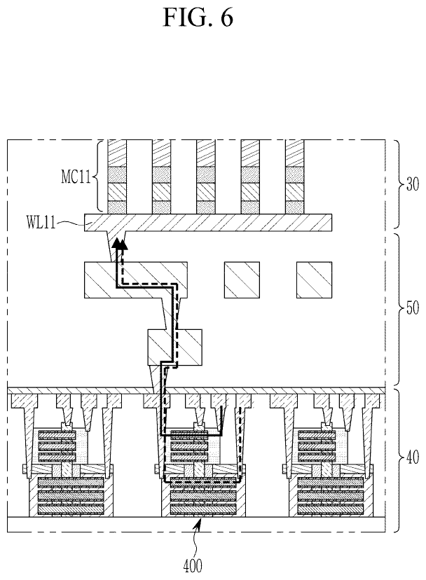

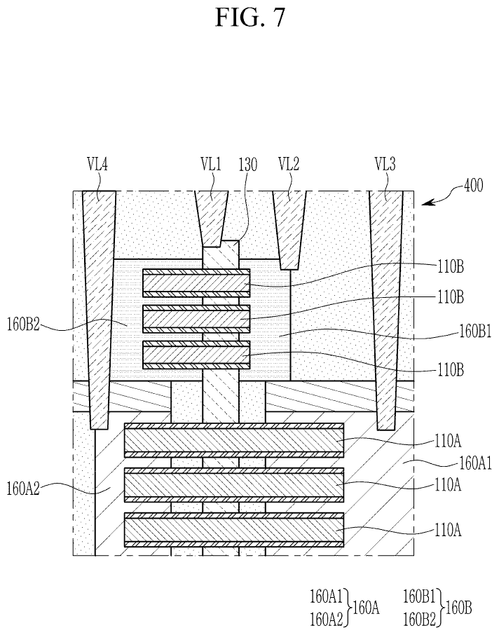

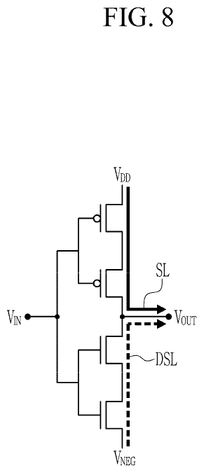

A semiconductor element 400 of the peripheral circuit 40 connected to one memory cell MC among the plurality of memory layers 31, 32, 33, and 34 of the semiconductor device according to some example embodiments will be described with reference to FIG. 6 to FIG. 8. FIG. 6 illustrates a simplified cross-sectional view of semiconductor elements of a peripheral circuit connected to a memory layer of a semiconductor device according to some example embodiments, FIG. 7 illustrates an enlarged view of the semiconductor element of the peripheral circuit of FIG. 6, and FIG. 8 illustrates a circuit diagram of the semiconductor element of the peripheral circuit of FIG. 7.

Referring to FIG. 6, the memory cell array 30 may be connected to the peripheral circuit 40 disposed under the memory cell array 30 through a connection wire layer 50. In FIG. 6, the word line WL11 and the memory cell MC11 of the first memory layer 31 of FIG. 1 are illustrated, but the peripheral circuit 40 may include a plurality of semiconductor elements 400 respectively connected to the plurality of bit lines BL11 to BL19 and BL21 to BL29 or the plurality of word lines WL11 to WL19, WL21 to WL29, and WL31 to WL39 of the memory cell array 30 of the memory device 3 according to the previously described example embodiments. The plurality of semiconductor element 400 may be decoders.

The semiconductor element 400 may include a plurality of first active patterns 110A and a plurality of second active patterns 110B stacked along a third direction DR3, which is a height direction (e.g., a vertical direction), a first source/drain area 160A disposed on both sides of the plurality of first active patterns 110A, a second source/drain area 160B disposed on both sides of the plurality of second active patterns 110B, and a common gate structure 130. The semiconductor element 400 may be a complementary field effect transistor (FET) stacked in the third direction DR3.

Referring to FIG. 7 and FIG. 8 together with FIG. 6, a selected voltage VDD and a de-selected voltage VNEG are respectively applied to the plurality of word lines WL11 to WL19, WL21 to WL29, and WL31 to WL39, and the plurality of bit lines BL11 to BL19 and BL21 to BL29 corresponding to the operation of the memory cells MC11, MC21, and MC31 of the plurality of memory layers 31, 32, 33, and 34 of the memory cell array 30 of the memory device 3. For example, the selected voltage VDD may be characterized as a first voltage and may be a source voltage (e.g., a positive voltage), and the de-selected voltage VNEG may be characterized as a second voltage and may be a negative voltage.

The semiconductor element 400 of the peripheral circuit 40 of the memory device 3 may include the plurality of first active patterns 110A and the plurality of second active patterns 110B stacked in the third direction DR3, the plurality of first active patterns 110A may be doped with a first type of impurity, and the plurality of second active patterns 110B may be doped with a second type of impurity. For example, the first type of impurity may be P-type, and the second type of impurity may be N-type. A width of the first plurality of active patterns 110A may be wider than that of the plurality of second active patterns 110B.

A first via VL1 may be connected to the common gate structure 130, a second via VL2 may be connected to a second source area 160B1 of the second source/drain area 160B, a third via VL3 may be connected to a first source area 160A1 of the first source/drain area 160A, and a fourth via VL4 may be connected to a first drain area 160A2 of the first source/drain area 160A and a second drain area 160B2 of the second source/drain area 160B.

The fourth via VL4 may be connected to the plurality of memory layers 31, 32, 33, and 34 of the memory cell array 30 through the connection wire layer 50.

A control signal may be applied to the first via VL1, the selected voltage VDD (e.g., the first voltage) may be applied to the second via VL2, and the de-selected voltage VNEG (e.g., the second voltage) may be applied to the third via VL3.

When the selected voltage VDD is applied (SL), the selected voltage VDD applied to the second via VL2 may be applied to the second source area 160B1 of the second source/drain area 160B to be transmitted to the second drain area 160B2 through the plurality of second active patterns 110B to be applied to the plurality of memory layers 31, 32, 33, and 34 of the memory cell array 30 through the fourth via VL4.

When the de-selected voltage VNEG is applied (DSL), the de-selected voltage VNEG applied to the third via VL3 may be applied to the first source area 160A1 and transmitted to the first drain area 160A2 through the plurality of first active patterns 110A4 to be applied to the plurality of memory layers 31, 32, 33, and 34 of the memory cell array 30 through the fourth via VL4.

As described above, the semiconductor element 400 of the peripheral circuit 40 that applies the selected signal VDD and the de-selected voltage VNEG to the memory cell array 30 of the memory device 3 according to some example embodiments includes a plurality of first active patterns 110A and a plurality of second active patterns 110B stacked along the third direction DR3, which is the height direction, so that the planar area of the area occupied by the peripheral circuit 40 may be reduced along the plane where the first direction DR1 and the second direction DR2, which are perpendicular to the third direction DR3, intersect.

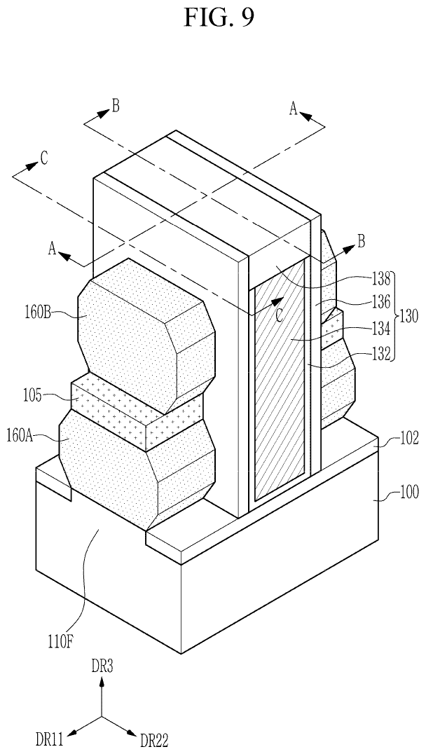

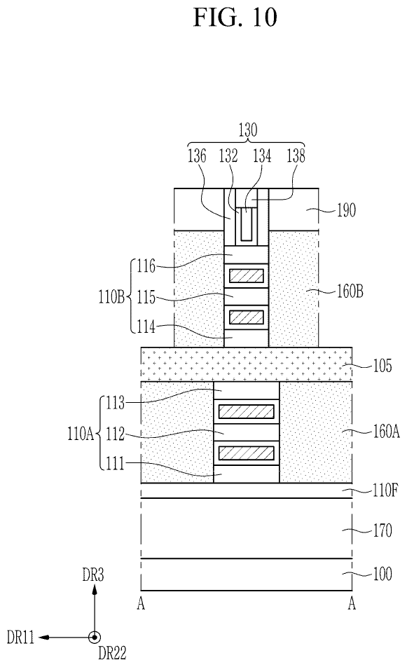

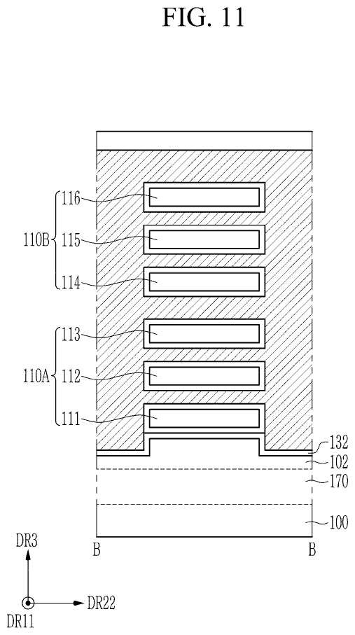

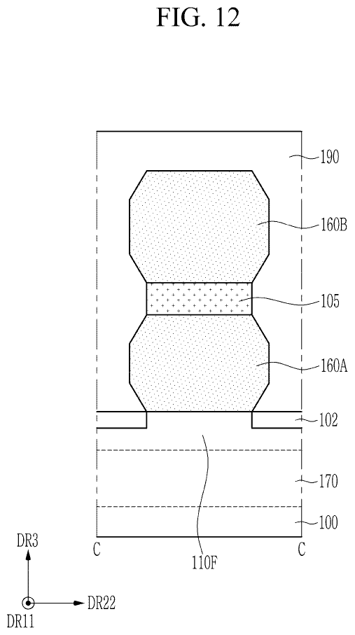

Hereinafter, an example of the semiconductor element 400 of the peripheral circuit 40 of the memory device 3 according to some example embodiments will be described in more detail with reference to FIG. 9 to FIG. 12. FIG. 9 illustrates a perspective view of a semiconductor element included in a peripheral circuit of a memory device according to some example embodiments, FIG. 10 illustrates a cross-sectional view taken along line A-A of FIG. 9, FIG. 11 illustrates a cross-sectional view taken along line B-B of FIG. 9, and FIG. 12 illustrates a cross-sectional view taken along line C-C of FIG. 9.

The semiconductor element 400 of the peripheral circuit 40 of the memory device 3 according to some example embodiments may include a substrate 100, a first active pattern 110A, a second active pattern 110B, a gate structure 130, a first source/drain area 160A, a second source/drain area 160B, a buffer layer 170, an insulating structure 105, and an interlayer insulating film 190.

The substrate 100 may be a bulk silicon or a silicon-on-insulator (SOI). The substrate 100 may be a silicon substrate, and the substrate 100 may include silicon germanium, a silicon germanium on insulator (SGOI), indium antimony, a lead telluride compound, indium arsenic, indium phosphide, gallium arsenic, or gallium antimonide. The substrate 100 may have an epitaxial layer formed on a base substrate.

The first active pattern 110A and the second active pattern 110B may be sequentially stacked on the substrate 100. The first active pattern 110A may be disposed on the substrate 100, and the second active pattern 110B may be disposed to be spaced apart from the first active pattern 110A thereon.

Each of the first active pattern 110A and the second active pattern 110B may extend in a direction parallel to the surface of the substrate 100, for example, in a first horizontal direction DR11. The first active pattern 110A and the second active pattern 110B may overlap each other along a height direction crossing the surface of the substrate 100, for example, the third direction DR3.

The first active pattern 110A and the second active pattern 110B may include silicon (Si) or germanium (Ge), which is an elemental semiconductor material. Each of the first active pattern 110A and the second active pattern 110B may include a compound semiconductor, for example, a group IV-IV compound semiconductor or a group III-V compound semiconductor. The group IV-IV compound semiconductor may be, for example, a binary compound or a ternary compound containing at least two or more of carbon (C), silicon (Si), germanium (Ge), and tin (Sn) or a compound doped with a group IV element thereto, and the group III-V compound semiconductor may be, for example, one of a binary compound, a ternary compound, or a quaternary compound formed by combining at least one of aluminum (Al), gallium (Ga), and indium (In) as a group III element and at least one of phosphorus (P), arsenic (As), and antimony (Sb) as a group V element.

The first active pattern 110A may include a plurality of lower sheet patterns, a first sheet pattern 111, a second sheet pattern 112, and a third sheet pattern 113, which are sequentially disposed on the substrate 100 and spaced apart from each other. The first sheet pattern 111, the second sheet pattern 112, and the third sheet pattern 113 may be parallel to each other and spaced apart from each other.

Similarly, the second active pattern 110B may include a plurality of upper sheet patterns, a fourth sheet pattern 114, a fifth sheet pattern 115, and a sixth sheet pattern 116, which are sequentially disposed on the first active pattern 110A and spaced apart from each other. The fourth sheet pattern 114, the fifth sheet pattern 115, and the sixth sheet pattern 116 may be parallel to each other and spaced apart from each other.

A fin pattern 110F may be disposed between the substrate 100 and the first active pattern 110A. The fin pattern 110F may be formed by etching a portion of the substrate 100, or may be an epitaxial layer grown from the substrate 100.

A field insulating film 102 may be disposed on the substrate 100. The field insulating film 102 may cover at least a portion of a side surface of the fin pattern 110F. The field insulating film 102 may be omitted.

The field insulating film 102 may include, for example, at least one of a silicon oxide, a silicon nitride, a silicon oxynitride, and combinations thereof.

The gate structure 130 may be disposed on the substrate 100 and the field insulating film 102. The gate structure 130 may cross the first active pattern 110A and the second active pattern 110B. The gate structure 130 may extend in a second horizontal direction DR22 parallel to the surface of the substrate 100 and intersecting the first horizontal direction DR11.

Each of the first active pattern 110A and the second active pattern 110B may extend along the first horizontal direction DR11 to penetrate the gate structure 130.

The gate structure 130 may surround a side surface of the first active pattern 110A and a side surface of the second active pattern 110B.

The gate structure 130 may include a gate insulating film 132, a gate electrode 134, a gate spacer 136, and a gate capping part 138.

The gate electrode 134 may be disposed on the substrate 100 and the field insulating film 102, and the gate electrode 134 may extend in the second horizontal direction DR22 to cross the first active pattern 110A and the second active pattern 110B.

The gate electrode 134 may be formed through a deposition process, but some example embodiments are not limited thereto.

The gate insulating film 132 may be disposed between the first active pattern 110A and the gate electrode 134 and between the second active pattern 110B and the gate electrode 134, and the gate insulating film 132 may be disposed between the fin pattern 110F and the gate electrode 134 and between the field insulating film 102 and the gate electrode 134.

The gate insulating film 132 may include at least one of, for example, a silicon oxide, a silicon oxynitride, a silicon nitride, and a high dielectric constant material having a dielectric constant greater than that of a silicon oxide.

The gate spacer 136 may be disposed on the substrate 100 and the field insulating film 102. The gate spacer 136 may be disposed along a side surface of the gate electrode 134.

The gate insulating film 132 may be disposed between the gate electrode 134 and the gate spacer 136.

The gate insulating film 132 may further extend along an inner surface of the gate spacer 136, and the gate insulating film 132 may be formed through a replacement process, but some example embodiments are not limited thereto.

The gate spacer 136 may include, for example, at least one of a silicon nitride, a silicon oxynitride, a silicon oxycarbide, a silicon boron nitride, a silicon boron carbonitride, a silicon oxycarbonitride, and combinations thereof.

The gate capping portion 138 may be disposed on an upper surface of the gate electrode 134.

The gate capping portion 138 may include, for example, at least one of a silicon nitride, a silicon oxynitride, a silicon oxycarbide, a silicon boron nitride, a silicon boron carbonitride, a silicon oxycarbonitride, and combinations thereof.

The first source/drain area 160A may be disposed on the upper surface of the substrate 100 and at least one side surface of the gate structure 130. The first source/drain area 160A may be connected to the first active pattern 110A. The first sheet pattern 111, the second sheet pattern 112, and the third sheet pattern 113 may each pass through the gate structure 130 to be connected to the first source/drain area 160A. The first source/drain area 160A may be electrically separated from the gate electrode 134 by the gate insulating film 132 and the gate spacer 136.

The second source/drain area 160B may be disposed on the upper surface of the first source/drain area 160A and at least both side surfaces of the gate structure 130. The second source/drain area 160B may be connected to the second active pattern 110B. The fourth sheet pattern 114, the fifth sheet pattern 115, and the sixth sheet pattern 116 may each pass through the gate structure 130 to be connected to the second source/drain area 160B. The second source/drain area 160B may be electrically separated from the gate electrode 134 by the gate insulating film 132 and the gate spacer 136.

The first source/drain area 160A and the second source/drain area 160B may each include an epitaxial layer. For example, first source/drain area 160A and second source/drain area 160B may each be formed by epitaxial growth.

The first source/drain area 160A and the second source/drain area 160B may have different conductivity types from each other. For example, the first source/drain area 160A may have a first conductivity type, and the second source/drain area 160B may have a second conductivity type different from the first conductivity type. For example, the first conductivity type may be a p-type, and the second conductivity type may be an n-type. In this case, the first active pattern 110A may be used as a channel area of PFET, and the second active pattern 110B may be used as a channel area of NFET.

When the first active pattern 110A has a p-type conductivity type, the first source/drain area 160A may include p-type impurities or impurities for limiting and/or preventing diffusion of p-type impurities. For example, the first source/drain area 160A may include at least one of B, C, In, Ga, Al, and a combination thereof.

When the second active pattern 110B has an n-type conductivity type, the second source/drain area 160B may include n-type impurities or impurities for limiting and/or preventing diffusion of the n-type impurities. For example, the second source/drain area 160B may include at least one of P, Sb, As, and a combinations thereof.

As described above, the first active pattern 110A and the first source/drain area 160A in contact with the first active pattern 110A may have a p-type conductivity type, and the second active pattern 110B and the second source/drain area 160B in contact with the second active pattern 110B may have an n-type conductivity type. The a width of the first active pattern 110A may be greater than a width of the second active pattern 110B along a direction parallel to the first horizontal direction DR11.

Generally, the charge mobility of a PFET may be smaller than that of an NFET. According to some example embodiments, the difference between the charge mobility of a PFET and the charge mobility of an NFET may be compensated by making the width of the first active pattern 110A greater than that of the second active pattern 110B.

The buffer layer 170 may be disposed between the substrate 100 and the first active pattern 110A. By forming the buffer layer 170 on the substrate 100 and forming a stacked structure on the buffer layer 170, defects that may occur in the semiconductor device due to tensile stress applied to the substrate may be limited and/or prevented.

The insulating structure 105 may be disposed on both side surfaces of the gate structure 130. The insulating structure 105 may be disposed between the first source/drain area 160A and the second source/drain area 160B. The insulating structure 105 may electrically separate the first source/drain area 160A and the second source/drain area 160B.

Each insulating structures 105 may include, for example, at least one of a silicon oxide, a silicon nitride, a silicon oxynitride, a silicon oxycarbide, a silicon boron nitride, a silicon boron carbonitride, a silicon oxycarbonitride, and combinations thereof, but some example embodiments are not limited thereto.

The interlayer insulating film 190 may be disposed on the substrate 100 and the field insulating film 102. The interlayer insulating film 190 may be formed to fill a space on the outer side surface of the gate spacer 136. For example, the interlayer insulating film 190 may cover the first source/drain area 160A, the second source/drain area 160B, and the insulating structure 105. The interlayer insulating film 190 is shown exposing only the upper surface of the gate structure 130, but this is only an example, and the interlayer insulating film 190 may cover the upper surface of the gate structure 130.

The interlayer insulating film 190 may include, for example, at least one of a silicon oxide, a silicon nitride, a silicon oxynitride, a silicon oxycarbide, a silicon boron nitride, a silicon boron carbonitride, a silicon oxycarbonitride, and a low dielectric constant material.

According to some example embodiments, the semiconductor element 400 of the peripheral circuit 40 of the memory device 3 includes the first active pattern 110A and the second active pattern 110B stacked along the third direction DR3, which is the height direction, so that the area occupied by the peripheral circuit 40 for driving the memory device 3 along the planar directions DR11 and DR22 may be narrowed. In contrast, if the semiconductor element 400 of the peripheral circuit 40 of the memory device 3 includes the first active pattern 110A and the second active pattern 110B adjacent to each other along the first planar direction DR11 or the second planar direction DR22, the area occupied by the peripheral circuit 40 for driving the memory device 3 along the planar directions DR11 and DR22 would be relatively wide.

However, as described above, the semiconductor element 400 of the peripheral circuit 40 of the memory device 3 according to some example embodiments includes the first active pattern 110A and the second active pattern 110B stacked along the height direction DR3, thereby narrowing the area of the area occupied by the peripheral circuit 40 along the planar directions DR11 and DR22.

The semiconductor element 400 of the peripheral circuit 40 of the memory device 3 according to some example embodiments may compensate for the difference between the charge mobility of a PFET and the charge mobility of an NFET by including the first active pattern 110A and the second active pattern 110B having different widths along the planar directions DR11 and DR22.

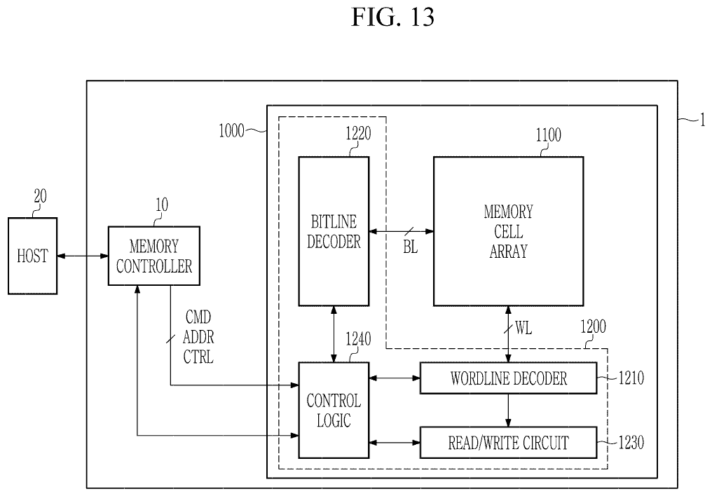

Referring to FIG. 13, a semiconductor device 1, including a memory device such as memory device 3 in FIG. 1, according to some example embodiments will be described. FIG. 13 illustrates a block diagram of a semiconductor device according to some example embodiments.

Referring to FIG. 13, the semiconductor device 1 may include a memory controller 10 and a memory device 1000, and the memory device 1000 may include a memory cell array 1100 and a peripheral circuit 1200. The peripheral circuit 1200 may include decoder circuits 1210 and 1220, a read/write circuit 1230, and a control logic 1240. The memory cell array 1100 may be the memory cell array 30 described above, and the peripheral circuit 1200 may include the semiconductor element 400 of the peripheral circuit 40 described above.

The memory controller 10 may generate an address ADDR, a command CMD, and a control signal CTRL according to a request from a host 20 to provide them to the memory device 1000. The memory controller 10 may generate the address ADDR, the command CMD, and the control signal CTRL according to a read request, a write request, an initialization request, and the like from the host 20.

The memory device 1000 may perform a write (or program), read, and initialization operations according to the address ADDR, the command CMD, and the control signal CTRL. The memory controller 10 may transmit data DATA to be written to the memory device 1000, or may receive data DATA read from the memory device 1000 to provide it to the host 20.

The decoder circuits 1210 and 1220 may include a word line decoder 1210 connected to a plurality of memory cells through the word lines WL and a bit line decoder 1220 connected to a plurality of memory cells through the bit lines BL. The control logic 1240 may control operations of the word line decoder 1210, the bit line decoder 1220, and the read/write circuit 1230 according to the address ADDR, the command CMD, and the control signal CTRL. Under the control of the control logic 1240, the read/write circuit 1230 may write data to at least one memory cell specified by the word line decoder 1210 and the bit line decoder 1220, and read data from at least one memory cell specified. The word line decoder 1210 and the bit line decoder 1220 may include the semiconductor element 400 of the peripheral circuit 40 described above.

When the control logic 1240 receives the command CMD instructing an initialization operation, the control logic 1240 may perform an initialization operation on a plurality of memory cells of the memory cell array 1100 through the word line decoder 1210 and the bit line decoder 1220.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While this disclosure has been described in connection with what is presently considered to be practical some example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor device comprising:
a plurality of word lines extending in a first direction;
a plurality of bit lines extending in a second direction crossing the first direction;
a plurality of memory cells in a plurality of areas in which the plurality of word lines and the plurality of bit lines intersect; and
a semiconductor element connected to at least one of the plurality of word lines and the plurality of bit lines, the semiconductor element including a first active pattern and a second active pattern overlapping the first active pattern along a height direction perpendicular to the first and second directions.

2. The semiconductor device of claim 1, wherein
the semiconductor element overlaps the plurality of memory cells along the height direction.

3. The semiconductor device of claim 2, wherein
each of the plurality of memory cells includes
a first electrode contacting one of the plurality of word lines,
a second electrode contacting one of the plurality of bit lines, and
a switch memory between the first electrode and the second electrode.

4. The semiconductor device of claim 3, wherein
the first electrode, the switch memory, and the second electrode overlap each other along the height direction.

5. The semiconductor device of claim 1, wherein
the first active pattern of the semiconductor element has a first type conductivity, and the second active pattern has a second type conductivity different from the first type conductivity.

6. The semiconductor device of claim 5, wherein
the first type conductivity is P-type and the second type conductivity is N-type.

7. The semiconductor device of claim 6, wherein
a width of the first active pattern is greater than a width of the second active pattern.

8. The semiconductor device of claim 1, wherein
the first active pattern of the semiconductor element includes a plurality of first sheet patterns, and the second active pattern of the semiconductor element includes a plurality of second sheet patterns.

9. The semiconductor device of claim 8, wherein
the plurality of first sheet patterns are stacked and spaced apart from each other along the height direction, and the plurality of second sheet patterns are stacked and spaced apart from each other along the height direction.

10. The semiconductor device of claim 9, wherein
the first active pattern of the semiconductor element has a first type conductivity, and the second active pattern has a second type conductivity different than the first type conductivity.

11. The semiconductor device of claim 10, wherein
the first type conductivity is P-type and the second type conductivity is N-type.

12. The semiconductor device of claim 11, wherein
a width of each of the plurality of first sheet patterns along a planar direction perpendicular to the height direction is greater than a width of each of the plurality of second sheet patterns along the planar direction perpendicular to the height direction.

13. The semiconductor device of claim 1, wherein
the semiconductor element includes
a first source/drain area connected to the first active pattern,
a second source/drain area connected to the second active pattern, and
a gate structure crossing the first active pattern and the second active pattern.

14. The semiconductor device of claim 13, wherein
the first source/drain area has a first type conductivity, and the second source/drain area has a second type conductivity different than the first type conductivity.

15. The semiconductor device of claim 14, wherein
the first type conductivity is P-type and the second type conductivity is N-type.

16. The semiconductor device of claim 15, wherein
a width of the first active pattern is greater than a width of the second active pattern.

17. The semiconductor device of claim 16, wherein
the first active pattern of the semiconductor element includes a plurality of first sheet patterns, and the second active pattern of the semiconductor element includes a plurality of second sheet patterns.

18. The semiconductor device of claim 17, wherein
the plurality of first sheet patterns are stacked and spaced apart from each other along the height direction, and the plurality of second sheet patterns are stacked and spaced apart from each other along the height direction.

19. The semiconductor device of claim 13, further comprising
a first via connected to the gate structure,
a second via connected to a second source area of the second source/drain area,
a third via connected to a first source area of the first source/drain area, and
a fourth via connected to a first drain area of the first source/drain area and a second drain area of the second source/drain area,
wherein the fourth via is connected to at least one of the plurality of word lines and the plurality of bit lines.

20. The semiconductor device of claim 19, wherein
a source voltage is applied as a selected voltage to the second via and a negative voltage is applied as a de-selected voltage to the third via.
